(19) United States
(12) Patent Application Publication
(10) Pub. No.: US 2018/0358388 A1
(43) Pub. Date: Dec. 13, 2018

(54) ARRAY SUBSTRATE AND DISPLAY DEVICE

(71) Applicant: WUHAN CHINA STAR OPTOELECTRONICS TECHNOLOGY CO., LTD., Wuhan, Hubei (CN)

(72) Inventor: Kaixiang ZHAO, Wuhan, Hubei (CN)

(73) Assignee: WUHAN CHINA STAR OPTOELECTRONICS TECHNOLOGY CO., L TD., Wuhan, Hubei (CN)

(21) Appl. No.: 15/539,807

(22) PCT Filed: May 15, 2017
(86) PCT No.: PCT/CN2017/084536

§ 371 Date: Jun. 26, 2017

(30) Foreign Application Priority Data
Apr. 27, 2017 (CN) 201710285719.8

(51) Int. Cl. H01L 27/12; H01L 29/786

(52) U.S. Cl. CPC H01L 27/1255; H01L 27/1222; H01L 27/124; G02F 1/1368; H01L 29/78621; H01L 29/78633; H01L 29/78675

(57) ABSTRACT

Disclosed is an array substrate, which includes a glass substrate arranged at a bottom layer. A gate line is arranged on the glass substrate. A plurality pairs of sources/drains are arranged on the array substrate, and at least one insulating layer is arranged between the sources/drains and the gate line. Along a direction from an output proximal end to an output distal end of the gate line, directly facing areas between the sources/drains and the gate line gradually decrease. A display device comprising the aforesaid array substrate is further provided. The array substrate and display device disclosed herein have a good display uniformity.

### CROSS-REFERENCE TO RELATED APPLICATIONS

This application claims the priority of Chinese patent application CN201710285719.8, entitled “Array substrate and display device” and filed on Apr. 27, 2017, the entirety of which is incorporated herein by reference.

### FIELD OF THE INVENTION

The present disclosure relates to the technical field of display, and in particular, to an array substrate and a display device.

### BACKGROUND OF THE INVENTION

Thin film transistor-liquid crystal display (TFT-LCD) is a common display device. When a TFT-LCD displays an image, the switching of image frames is achieved by scanning of a gate line. The gate line is a metal line, which has a certain resistance. As a transmission distance increases, a voltage on a scanning line will decrease, and this phenomenon is called as feedthrough. The expression of a feedthrough on the gate line in a liquid crystal display panel in the prior art is:

$$Δ Vp = \frac{{C}_{gs}}{{C}_{gs} + {C}_{lc} + {C}_{s}} * {V}_{ghl}$$

wherein ΔVₚ represents a feedthrough value, C_{gs} represents a capacitor between the gate line and a source/drain of a switching element, C_{lc} represents a liquid crystal capacitor, Cₛ represents a storage capacitor, and V_{ghl} represents a difference between an ideal input voltage and an actual input voltage. Along a direction from an output proximal end to an output distal end of the gate line (i.e. a direction from an end of the gate line near to a scanning signal driving circuit to the other end far therefrom), the actual input voltage of the gate line gradually decreases, while the ideal input voltage does not change. Therefore, V_{ghl} gradually increases. That is, the feedthrough value ΔVₚ gradually increases along the direction from the output proximal end to the output distal end of the gate line. The change of ΔVₚ on the liquid crystal panel may cause the result that the image is brighter near an input end of the gate line, while the image is darker far from the input end of the gate line, which affects a display uniformity of the panel.

### SUMMARY OF THE INVENTION

In order to solve a nonuniform display of a panel due to the change of a feedthrough in the prior art, the present disclosure provides an array substrate and a display device. Compared with the display device in the prior art, the array substrate and the display device according to the present disclosure have a better display uniformity.

The present disclosure provides an array substrate, which comprises a glass substrate arranged at a bottom layer. A gate line is arranged on the glass substrate, and a plurality pairs of sources/drains are arranged on the array substrate. At least one insulating layer is arranged between the sources/drains and the gate line, wherein directly facing areas between the sources/drains and the gate line gradually decrease along a direction from an output proximal end to an output distal end of the gate line.

According to the present disclosure, the directly facing areas between the sources/drains and the gate line gradually decrease, so that ΔVₚ is relatively uniform on an entire panel, and a display uniformity of the panel can be ensured.

As a further improvement on the present disclosure, the array substrate further comprises an active layer, which comprises conductive channels. The sources and the drains are connected to each other through the conductive channels. The directly facing areas between the sources/drains and the gate line are directly facing areas between the conductive channels and the gate line when viewed in a direction perpendicular to the array substrate.

Further, the glass substrate is provided with the active layer, a first insulating layer, the gate line, a second insulating layer and a second conductive layer in sequence, and the second conductive layer comprises the sources/drains.

Further, the first insulating layer and the second insulating layer are provided with via holes, and the sources/drains are connected to the conductive layers through different via holes respectively.

Further, the active layer further comprises source regions and drain regions located on two sides of the conductive channels. The source regions are connected to the sources, and the drain regions are connected to the drains.

Further, a width of the gate line gradually decreases along the direction from the output proximal end to the output distal end of the gate line.

Further, the width of the gate line decreases stepwise.

Further, the gate line is symmetrical about a centerline of a transmission direction, and the gate line has stepped structures on both sides of the centerline.

By changing the width of the gate line, the directly facing areas between the sources/drains and the gate line gradually decrease. The method is simple and practical.

Further, along the direction from the output proximal end to the output distal end of the gate line, widths of the conductive channels gradually decrease in the transmission direction.

According to another aspect of the present disclosure, a display device is further provided. The display device comprises the aforesaid array substrate.

According to the present disclosure, the directly facing areas between the sources/drains and the gate line are changed, so that a feedthrough is constant at all positions of the gate line, and the display uniformity of the panel can be improved.

### BRIEF DESCRIPTION OF THE DRAWINGS

The present disclosure will be described in a more detailed way below based on embodiments and with reference to the accompanying drawings, in the drawings:

FIG. 1 schematically shows wiring of an array substrate in the prior art;

FIG. 2 schematically shows a structure of an array substrate according to one embodiment of the present disclosure;

FIG. 3 schematically shows wiring of an array substrate according to one embodiment of the present disclosure; and

FIG. 4 schematically shows wiring of an array substrate according to one embodiment of the present disclosure.

In the drawings, the same components are represented by the same reference signs, and the size of each component does not represent the actual size of the corresponding component.

### DETAILED DESCRIPTION OF THE EMBODIMENTS

The present disclosure will be described in a more detailed way below with reference to the accompanying drawings.

In a feedthrough formula, C_{gs} represents a capacitor between a gate line and a source/drain of a switching element. That is, the gate line and the source/drain are equivalent to one capacitor, and the capacitance C_{gs} equals to a dielectric constant multiplied by a ratio of an area between two plates of the capacitor to a distance between the two plates. The dielectric constant is a constant, and the distance between the two plates is determined by a distance between the gate line and the source/drain. It can be understood by those skilled in the art that, the area between the two plates is a directly facing area between the gate line and the source/drain. Hence, the directly facing areas between the gate line and the sources/drains gradually decrease along a direction from an output proximal end to an output distal end of the gate line, so that the feedthrough ΔVₚ gradually decreases along the direction from the output proximal end to the output distal end of the gate line. In this manner, ΔVₚ tends to be consistent from the output proximal end to the output distal end of the gate line by adjusting the directly facing areas between the gate line and the sources/drains, so that an output voltage of the whole panel is uniform and a display uniformity of the panel can be improved.

FIG. 1 schematically shows wiring of an array substrate in the prior art. The present disclosure is based on changing a capacitor between a gate line and a source/drain layer. In the prior art, sources and drains are generally connected to each other through conductive channels, which are generally arranged corresponding to the gate line. Hence, the purpose of the present disclosure can be achieved by changing the capacitors between the conductive channels and the gate line. In the prior art, the conductive channels are generally located on an active layer. In order to illustrate the technical problem to be solved and the technical means to be used in the present disclosure, only the gate line and the active layer are shown in FIG. 1. FIG. 1 schematically shows the wiring of the array substrate when viewed in a direction perpendicular to the array substrate. A gate line 10 is located at a bottom layer, and the active layer 11 is located above the gate line 10. It can be known by those skilled in the art that, a plurality of conductive channels 12 are arranged on the gate line 10 along an output direction of the gate line. As shown in FIG. 1, directly facing regions between the active layer and the gate line are the conductive channels 12. As shown in FIG. 1, in the prior art, since a width of the gate line and a size of each conductive channel 12 are uniform and constant, directly facing areas between the gate line 10 and the conductive channels 12 are constant along the direction from the output proximal end to the output distal end of the gate line. That is, directly facing areas between the gate line 10 and the sources/drains are constant.

The present disclosure is based on changing the capacitor between the gate line and the source/drain layer. In order to illustrate the technical problem to be solved and the technical means to be used in the present disclosure, only an essential portion in the present disclosure is illustrated, and as the prior art, other portions of the array substrate are not repeatedly described herein.

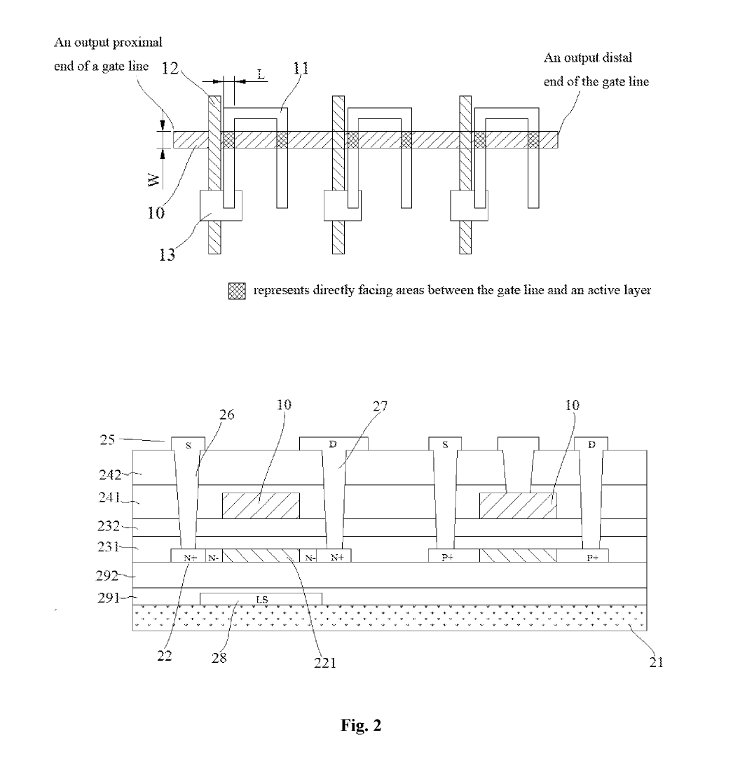

According to one embodiment of the present disclosure, an array substrate is provided. FIG. 2 schematically shows a structure of the array substrate. The array substrate comprises a glass substrate 21 arranged at a bottom layer, and a gate line 10 is arranged on the glass substrate 21. A plurality pairs of sources S/drains D are arranged on the array substrate, and at least one insulating layer is arranged between the sources S/drains D and the gate line 10. Along a direction from an output proximal end to an output distal end of the gate line, directly facing areas between the sources/drains and the gate line gradually decrease.

As shown in FIG. 2, according to the present embodiment, from the glass substrate 21 upwards, the array substrate comprises an active layer 22, a first insulating layer 23, the gate line 10, a second insulating layer 24 and a second conductive layer 25 in sequence. The second conductive layer 25 comprises the sources S/drains D. The active layer 22, which comprises a plurality of conductive channels 221, is arranged on the glass substrate. The first insulating layer 23 is arranged on the active layer 22, and comprises an insulating layer 231 formed by SiOx and an insulating layer 232 formed by SiNx. The gate line 10 is arranged on the first insulating layer 23 corresponding to the conductive channels 221. A second insulating layer 24 is arranged on the gate line 10, and comprises an insulating layer 241 formed by SiNx and an insulating layer 242 formed by SiOx. First via holes 26 and second via holes 27 are arranged through the first insulating layer 23 and a part of the second insulating layer 24. The sources S are connected to source regions on the active layer through the first via holes 26 so that connection between the sources S and the conductive channels 221 can be achieved. The drains D are connected to drain regions on the active layer 22 through the second via holes 27, so that connection between the drains D and the conductive channels 221 can be achieved.

According to one embodiment of the present disclosure, a light shielding layer 28 is arranged on the glass substrate 21 corresponding to the conductive channels 221 so as to prevent backlight from irradiating the conductive channels 211. In this manner, a performance of switching devices will not be affected. A third insulating layer 29 is arranged between the light shielding layer 28 and the active layer 22. The third insulating layer 29 comprises an insulating layer 291 formed by SiNx and an insulating layer 292 formed by SiOx.

According to one embodiment of the present disclosure, the active layer 22 is made of low temperature polysilicon material and comprises ion heavily doped regions N+ arranged on two sides of the conductive channels 221 and the conductive channels 221 arranged between the ion heavily doped regions N+. Each of the ion heavily doped regions N+ comprises a drain region connected to the drain of a switching element and a source region connected to the source of the switching element.

According to one embodiment of the present disclosure, ion lightly doped regions are arranged between the conductive channels 221 and the ion heavily doped regions. Specifically, as shown in FIG. 2, ion lightly doped regions N− are arranged between the channels and the ion heavily doped regions N+ so as to reduce the effect on on-current of the device.

According to some embodiments, other layers, such as a flat layer and a common electrode layer, are arranged on the second conductive layer of the array substrate, which will not be repeatedly described here.

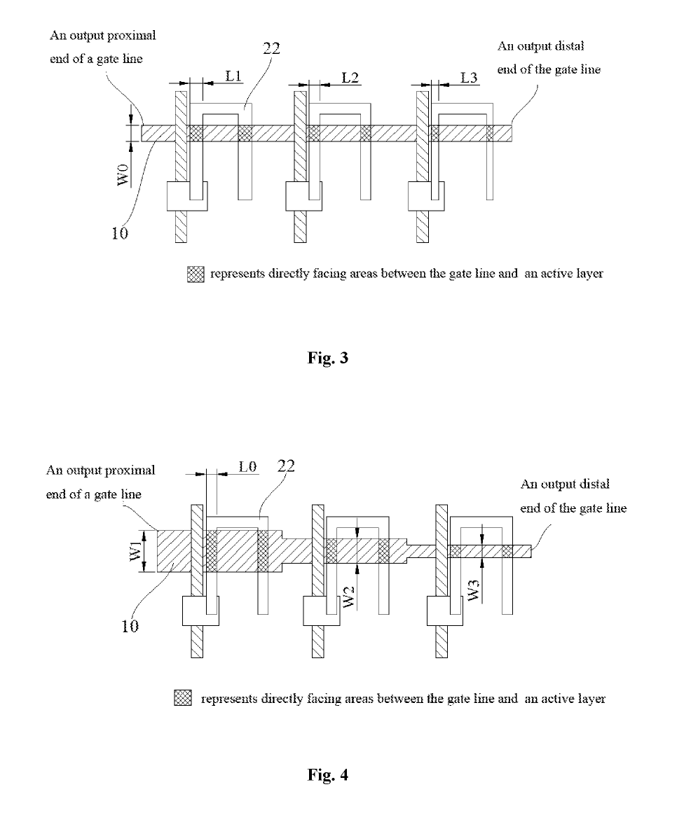

As shown in FIG. 3, one embodiment of the present disclosure is based on changing the conductive channels. A width of the gate line 10 is constant and represented by W0. Along the direction from the output proximal end to the output distal end of the gate line, widths of the conductive channels gradually decrease along a transmission direction, which is shown as L1>L2>L3 in FIG. 3.

The transmission direction according to the present disclosure is a transmission direction of signals on the gate line. According to the present disclosure, the signals are transmitted on the gate line from the output proximal end to the output distal end.

According to one embodiment, along the direction from the output proximal end to the output distal end, a width of the gate line 10 gradually decreases. For example, the gate line can be arranged as a trapezoid. A longer bottom edge is the output proximal end of the gate line, while a shorter bottom edge is the output distal end of the gate line.

As shown in FIG. 4, one embodiment of the present disclosure is based on changing the gate line. Along the direction from the output proximal end to the output distal end of the gate line, a width of the gate line decreases stepwise. The output proximal end of the gate line is arranged as a widest step, while the output distal end of the gate line is arranged as a narrowest step.

As shown in FIG. 4, the gate line is symmetrical about a centerline of a transmission direction, and the gate line has stepped structures on both sides of the centerline. As shown in FIG. 4, along the direction from the output proximal end to the output distal end of the gate line, widths of the bottom edges are respectively W1, W2, and W3, wherein W1>W2>W3.

According to the two embodiments as shown in FIG. 3 and FIG. 4, along the direction from the output proximal end to the output distal end of the gate line, the directly facing areas between the conductive channels and the gate line gradually decrease. That is, the directly facing areas between the sources/drains and the gate line gradually decrease. In this manner, the feedthrough on the panel is uniform, and the display uniformity of the panel can be ensured.

The present disclosure is explained in detail with reference to preferred embodiments hereinabove, but the embodiments disclosed herein can be improved or substituted with the equivalents without departing from the protection scope of the present disclosure. In particular, as long as there are no structural conflicts, the technical features disclosed in each and every embodiment of the present disclosure can be combined with one another in any way, and the combined features formed thereby are within the protection scope of the present disclosure. The present disclosure is not limited by the specific embodiments disclosed herein, but includes all technical solutions falling into the protection scope of the claims.

1. An array substrate, comprising a glass substrate arranged at a bottom layer, a gate line being arranged on the glass substrate, a plurality pairs of sources/drains being arranged on the array substrate, at least one insulating layer being arranged between the sources/drains and the gate line,
wherein directly facing areas between the sources/drains and the gate line gradually decrease along a direction from an output proximal end to an output distal end of the gate line.

2. The array substrate according to claim 1, wherein the array substrate further comprises an active layer, which comprises conductive channels;
wherein the sources and the drains are connected to each other through the conductive channels; and
wherein directly facing areas between the sources/drains and the gate line are directly facing areas between the conductive channels and the gate line when viewed in a direction perpendicular to the array substrate.

3. The array substrate according to claim 2, wherein the glass substrate is provided with the active layer, a first insulating layer, the gate line, a second insulating layer and a second conductive layer in sequence, and the second conductive layer comprises the sources/drains.

4. The array substrate according to claim 3, wherein the first insulating layer and the second insulating layer are provided with a plurality of via holes, and the sources/drains are connected to the conductive channels through different via holes respectively.

5. The array substrate according to claim 4, wherein the active layer further comprises source regions and drain regions located on two sides of the conductive channels, the source regions being connected to the sources, the drain regions being connected to the drains.

6. The array substrate according to claim 1, wherein a width of the gate line gradually decreases along the direction from the output proximal end to the output distal end of the gate line.

7. The array substrate according to claim 2, wherein a width of the gate line gradually decreases along the direction from the output proximal end to the output distal end of the gate line.

8. The array substrate according to claim 3, wherein a width of the gate line gradually decreases along the direction from the output proximal end to the output distal end of the gate line.

9. The array substrate according to claim 4, wherein a width of the gate line gradually decreases along the direction from the output proximal end to the output distal end of the gate line.

10. The array substrate according to claim 5, wherein a width of the gate line gradually decreases along the direction from the output proximal end to the output distal end of the gate line.

11. The array substrate according to claim 6, wherein the width of the gate line decreases stepwise.

12. The array substrate according to claim 11, wherein the gate line is symmetrical about a centerline of a transmission direction, and the gate line has stepped structures on both sides of the centerline.

13. The array substrate according to claim 1, wherein along the direction from the output proximal end to the output distal end of the gate line, widths of the conductive channels gradually decrease in a transmission direction.

14. The array substrate according to claim 2, wherein along the direction from the output proximal end to the output distal end of the gate line, widths of the conductive channels gradually decrease in a transmission direction.

15. The array substrate according to claim 3, wherein along the direction from the output proximal end to the output distal end of the gate line, widths of the conductive channels gradually decrease in a transmission direction.

16. The array substrate according to claim 4, wherein along the direction from the output proximal end to the output distal end of the gate line, widths of the conductive channels gradually decrease in a transmission direction.

17. The array substrate according to claim 5, wherein along the direction from the output proximal end to the output distal end of the gate line, widths of the conductive channels gradually decrease in a transmission direction.

18. The array substrate according to claim 6, wherein along the direction from the output proximal end to the output distal end of the gate line, widths of the conductive channels gradually decrease in a transmission direction.

19. The array substrate according to claim 11, wherein along the direction from the output proximal end to the output distal end of the gate line, widths of the conductive channels gradually decrease in a transmission direction.

20. A display device comprising an array substrate, the array substrate comprising a glass substrate arranged at a bottom layer, a gate line being arranged on the glass substrate, a plurality pairs of sources/drains being arranged on the array substrate, at least one insulating layer being arranged between the sources/drains and the gate line,
wherein directly facing areas between the sources/drains and the gate line gradually decrease along a direction from an output proximal end to an output distal end of the gate line.
